(19) United States
(12) Patent Application Publication
(10) Pub. No.: US 2005/0134436 A1
(43) Pub. Date: Jun. 23, 2005

(54) Multiple RFID anti-collision interrogation method

(76) Inventor: George Brookner, Norwalk, CT (US)

Correspondence Address: PERMAN & GREEN, 425 POST ROAD, FAIRFIELD, CT, 06824, US

(21) Appl. No.: 10/740,983

(22) Filed: Dec. 19, 2003

(51) Int. Cl. H03M 1/00

(52) U.S. Cl. 340/14.69

(57) ABSTRACT

A method and system to selectively identify one RFID tag response from a plurality of RFID tag responses. An interrogation signal is transmitted. If more than one RFID tag response is detected a signal is transmitted that can disable all responding tags, or all responding tags except the tag or tags of interest. The tag of interest, if not already enabled, is enabled and interrogated.

### BACKGROUND OF THE INVENTION

1. Field of the Invention

The present invention generally relates to products that will rely on radio frequency identification tags (RFID) to impart information in response to an applied RF signal and, more particularly, to identifying and isolating RFID tag responses from one another.

2. Brief Description of Related Developments

Radio Frequency Identity or Identification (RFID) is a means of storing and retrieving data through electromagnetic transmission to a RF compatible integrated circuit.

Read-only transponders store information that can be electronically “read”. The stored information can be for example, a unique code. In some systems, a signal can be sent to a RFID tag, which charges the tag and allows the information stored in the tag to be returned.

RFID systems have several basic components or technical characteristics that define them. Referring to FIG. 1, generally, these are a reader 2, including an antenna 7 (the device that is used to read and/or write data to RFID tags), a tag 8 (a device that transmits the data to a reader) and the communication pathway 9 between them (RFID uses a defined radio frequency and protocol to transmit and receive data from tags). The reader 2 can be coupled to a computer 4, which might also be connected to a database 6.

RFID tags are generally classified as active tags and passive tags, as defined by their power source.

Active tags contain both a radio frequency transceiver and a battery to power the transceiver. Because there is a powered transceiver on the tag, active tags have substantially more range (approximately 300 feet or more) than passive or “active/passive tags.” Active tags are also considerably more expensive than passive tags and, as with any battery-powered product, the batteries must be replaced periodically or the product life cycle is less than the battery life.

Passive tags can be either battery or non-battery operated, as determined by the intended application. Passive tags reflect the RF signal transmitted to them from a reader or transceiver and add information by modulating the reflected signal. A passive tag does not use a battery to boost the energy of the reflected signal. A passive tag may use a battery to maintain memory in the tag or power the electronics that enable the tag to modulate the reflected signal. Battery-less (“pure passive” or “beam powered”) tags do not contain an internal power source such as a battery. These purely passive or “reflective” tags rely upon the electromagnetic energy radiated by an interrogator to power the RF integrated circuit that makes up the tag itself.

There is a version of a passive tag that does contain a battery. This type of passive tag with a battery (“active/passive”) has some of the enhanced, and speed attributes of a true active tag, but still communicates in the same method, as do other passive tags. These active/passive tags that do contain an internal power source, usually are much more complex integrated circuits with multiple components.

RF tags can also be distinguished by their memory type. Read/write memory, can be read as well as written into. Its data can be dynamically altered. Read only (typically “chipless”) type of tag memory is factory programmed and cannot be altered after the manufacturing process. Its data is static.

The tags and a reader communicate by wireless signal in a process known as coupling. Two methods of wireless signal coupling distinguish and categorize RFID systems. Close proximity electromagnetic or inductive coupling systems and propagating electromagnetic waves. Coupling is via antenna structures forming an integral feature in both tags and readers.

In a situation where a reader is in the general proximity of a single tag, as illustrated in FIG. 1, the communication between the tag 8 and the reader 2 is generally uncomplicated. There are generally no other signals that might interfere with the coupling signal 9. However, when a number of RFID tags are all in the proximity of a reader/transceiver's generated interrogation signal, all of the devices will tend to respond at the same time causing the reader/transceiver to be bombarded with unintelligible data. Thus, there is a need to be able to simultaneously read several tags and the data from several tags in the same RF field. However, in order to read multiple tags simultaneously, the tag and reader must be designed to detect that more than one tag is active. If not, the interrogated tags will all backscatter the carrier at the same time, and garble amplitude-modulated waveforms causing “collisions.” The result is that data will not be intelligible to the reader. The interface mechanism between the tag and the reader must be such that one tag's transmission of data or information is distinguished from another tag's simultaneous transmission.

Ways to avoid these data collisions generally include sufficient physical separation of the RFID tags sufficiently so the electromagnetic field from the reader/transceiver is only sensed by one tag at a time. The RFID antenna could also be positional or directional so that only one tag is interrogated at a time. Another common method of resolving the data collisions is to reduce the output frequency and/or power of the reader/transceiver such that it must be moved very close to a tag before the tag has enough received energy to respond. Another method involves the transceiver knowing the individual tag's ID number and selectively activating individual tags.

In an environment where a number of products having RFID tags are in the same proximity, a reader/transceiver, upon generating its interrogation electromagnetic transmission, will receive a response from all RFID tags within the generated electromagnetic field. In order to be able to isolate one RFID tag response from another response, it would be helpful to be able to provide for response isolation such that the reader/transceiver, upon sensing return signals, may differentiate one RFID tag response from another.

### SUMMARY OF THE INVENTION

The present invention is directed to selectively identifying at least one RFID tag from another RFID during interrogation of a plurality of RFID tags. In one embodiment, the method includes transmitting an interrogation signal to one or more RFID tags in a plurality of RFID tags. A tag of interest is identified in the reader by a unique identifier associated with the tag of interest that is transmitted to the reader in response to the interrogation signal and identified by the reader. The reader then generates a signal that is transmitted to the tag that disables all of the tags being interrogated. The reader then generates or transmits a signal that turns on or enables the tag of interest corresponding to the unique identifier. The reader can then acquire data associated with the tag of interest after interrogating the tag. Alternately, the reader may generate a signal transmitted to the tags, that instructs all of the tags with the exception of a tag with a specific unique identifier, to be disabled.

Digital encryption and signing techniques will be imposed in one embodiment of this invention to protect the system from fraudulent attempts to either monitor RFID transmissions or to enact attacks on the system intended to modify tag responses. Typical of an attack to be thwarted is that by an intruder acting as a “man-in-the-middle” between the reader/transceiver and the RFID tag intent upon modifying tag responses for some personal gain. To counter such threat, each RFID tag will have its own unique identity characterized by the incorporation of public key cryptography and digital signing techniques. The tag can include within its memory a private key that is used to sign data being transmitted in response to an interrogation command by the reader/transceiver. The computing system associated with the reader/transceiver has within its database the matching public key for the tag's private key. The public key is the only mathematical application that can verify the signature generated by the tag's private key. Further, to protect the privacy of the data being transmitted by the RFID tag, encryption is used to hide the data context.

Utilizing standard public key encryption techniques, a comparison of signatures received from tags is made to a database associated with the reader/transceiver. The authentication of RFID tag data with its associated signature assures that the message is as transmitted from a specific tag.

An additional deterrent to inhibiting fraudulent intrusion will be to verify that the tag public key is authentic, whereby the data elements of the tag's transmission, have added to them the tag's public key, and together are input to a standardized hash function, which resulting value is, in turn, operated upon by a standardized digital signature function utilizing the tag's imbedded vendor private key. The output of the signature function is a signature value. The signature value is supplied to the signature verifier of the reader/transceiver. Likewise supplied to the signature verifier function is the tag's vendor public key along with the hash value of the aforementioned data elements hash value inclusive of the tag's public key. The signature verifier utilizes the vendor public key to verify the signature on the data elements hash value, and consequently the tag's public key, and subsequently verifying the hash value under the signature with the provided unsigned hash value.

### BRIEF DESCRIPTION OF THE DRAWINGS

The foregoing aspects and other features of the present invention are explained in the following description, taken in connection with the accompanying drawings, wherein:

FIG. 1 is a block diagram of an RFID system.

FIG. 2 is a block diagram of an RFID system incorporating features of the present invention.

FIG. 3 is a block diagram of a multiple RFID system incorporating features of the present invention.

FIG. 4 is a flow chart illustrating an embodiment of a method incorporating features of the present invention.

FIG. 5 illustrates one embodiment of a digital verification process of a RFID tag with its remote reader/transceiver system.

FIG. 6 represents one embodiment of a RFID tag public key validation process.

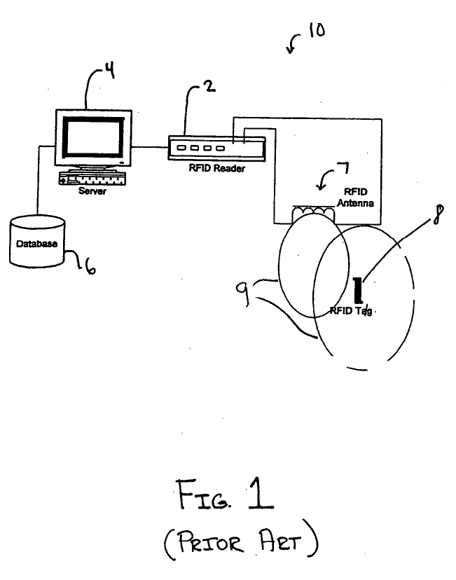

### DETAILED DESCRIPTION OF THE PREFERRED EMBODIMENT(s)

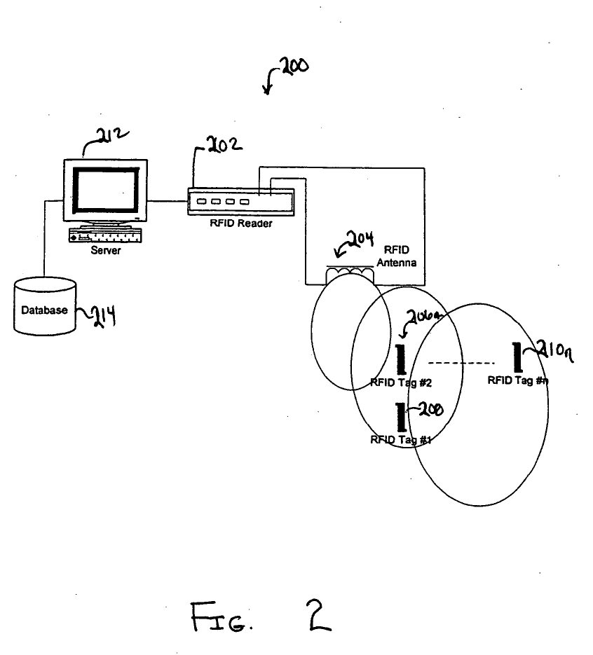

FIG. 2 illustrates a perspective view of a system 200 incorporating features of the present invention. Although the present invention will be described with reference to the embodiment shown in the drawings, it should be understood that the present invention could be embodied in many alternate forms of embodiments. In addition, any suitable size, shape or type of elements or materials could be used.

An automatic identification system 200 using radio frequency identification (RFID) has a reader 202 which transmits a signal at a given frequency to all RFID tags 206a, 208-210n within its range. These RFID tags 206a-210n, upon being interrogated, will each return a signal to the reader 202. When the tags are “activated” by the reader 202, a dialogue is established according to a predefined communication protocol for exchanging data. The reader 202 and the RFID tags 206a-210n communicate via electromagnetic fields created by the reader 202 and the RFID tags 206a-210n. A battery, the electromagnetic field, or a combination of both provides the power that activates the interrogated tag. Each RFID tag's integrated circuit transmits information about the tag, its stored data and its unique ID. The reader 202 receives the signals and transforms the signal into for example binary data or an otherwise suitable signal. Likewise, the reader 202 can send data to the RFID tags where the data or information is reconverted into digital information by the RFID tag. RFID technology is commonly applied to notify an RFID reader of a RFID tag location and provide data about the tag or about its environment. Also, an RFID tag can have information added and deleted from it as it goes through the supply chain. Any suitable data or information can be provided to or from a tag.

FIG. 2 depicts an infrastructure compatible with reading and modifying RFID tags according to the present invention. The RFID antenna 204 transmits an interrogation signal that is received by one or more of the RFID tags 206a-210n. The present invention can be applied to any number of tags. The tags, 206a-210n, once interrogated, generate a reply signal that is coupled to the RFID antenna 204 and transmitted to the RFID reader 202. The reply signal can include a unique identifier that identifies each tag uniquely. The identifier can be part of the header information in the signal, such as for example a packet based signal. The RFID reader 202 could be coupled to a computer or server 212 that is coupled to a database 214.

Referring to FIG. 2, if the reader 202 detects that more than one tag in the group 206a-210n is responding to the interrogation signal, the reader 202 transmits a signal that terminates signals from all RFID tags 206a-210n in the reception area. The identifier or ID information received by the reader from the tags in response to the interrogation signal can be used to identify one or more specific tags of interest. Although the identifier information sent by each tag in response to an interrogation signal will be received and deciphered by the reader, the reader may not be able to identify a source of data, or data that may be received. In one embodiment, the termination signal transmitted by the reader in response to the receipt of multiple signals from a plurality of tags might omit or not include a specific tag ID, if it is desired to interrogate that specific tag. Thus, all tags except the tag of interest would be disabled. If all tags are disabled, or the desired tag is not enabled, the reader 202 can, after all other tags are disabled, enable the specific tag and interrogate it for information. The RFID reader 2027 is capable of reading tag data as well as changing the stored data.

Each RFID tag 206a-210n has its own unique identity that can be authenticated and verified, using for example, public key cryptography and digital signing techniques.

In one embodiment, the signatures received from tags can be authenticated by server 212 using public key related certificate compared with information stored in a database 214 that is associated with the reader/transceiver 202.

In one embodiment, the reader/transceiver 202 can accept any RFID tag signal returned to it and identify a clear to send packet, or a specific tag's ID against a specific tag. The reader/transceiver 202 can transmit a terminating signal in order to terminate signals from all RFID tags in the reception area except for the one whose clear to send packet or tag ID is acknowledged. The data associated with that specific tag could then be retrieved or updated.

In one embodiment, the reader 202 can then send a signal to turn on all of the tags, interrogate the tags, and isolate another tag of interest based on the identifiers received. Each tag of interest is enabled in order to retrieve or update the associated data. Then, another RFID tag's clear to send packet or tag ID is acknowledged and all tags, other than the one whose clear to send packet or tag ID is to be acknowledged, are turned off. Alternatively, the system 200 could maintain an initial list of identifiers received from the initial interrogation. Each tag of interest would then be enabled and disabled in order to retrieve and/or update the associated data.

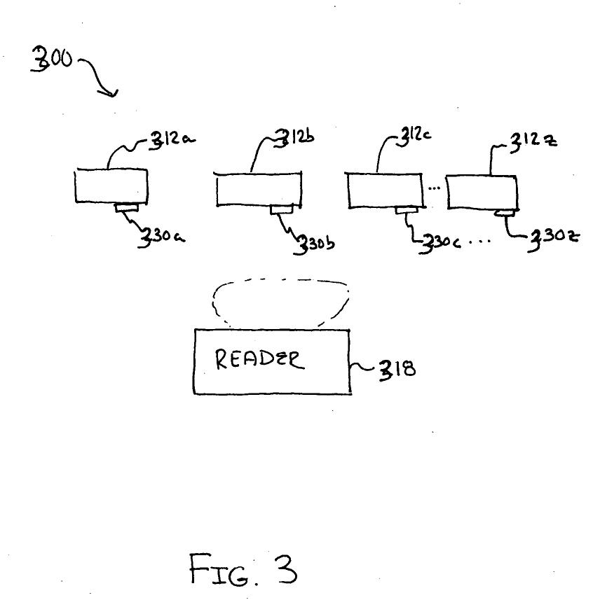

Referring to FIG. 3, a system 300 is shown incorporating features of the present invention. A number of items 312a-312z are shown that each have a respective RFID tag 330a-330z. The items 312a-312z are shown being in the same general proximity to each other, although in alternate embodiments, any suitable arrangement can be utilized. The items 312a to 312z may or may not be related, however each RFID tag 330a-330z can be programmed with a unique identity to enable the identification of one tag signal from another. The identity or information stored in each tag can encompass a wide range of data or information, including for example, a product code, a serial number, or a string of alphanumeric values or series of bits. Each bit position could be representative of a unique characteristic of the tag or an item associated with the tag.

Since the general information in each tag can be known, such as for example, the unique identifier information, a user can selectively program the reader 318 to enable or disable a specific tag or group of tags 330a-330z, based on the identifier or other information known to be stored in each tag. For example, certain date values or data sequences can be associated with an item, and this information can be stored in a tag corresponding to the item. Isolating tags by these unique date values or data sequences can reduce or eliminate the collisions caused by multiple tags responding to an interrogation. Each tag 330a-330z is capable of being enabled or disabled from a remote location with a remote signal. By transmitting an enabling signal or signals, a user can selectively command one or more tags to be enabled or alternatively to be disabled. Thus, a tag can be turned on or off. The user can select one tag or a group of tags bearing the same or related information and enable or disable the tag or tags. By selectively choosing the category or categories of data, as the selection criteria, the user can narrow the field of tags that will respond to interrogation until only the desired tag is available. In this fashion, a desired tag of interest can relatively easily be located.

In one embodiment, the present invention is adapted to scan an inventory made up of different metering models, times of manufacture, meter configurations and the like. The result of such inventory RFID reading is accuracy of inventory count, as well as to enable the re-identification or meter information updates to occur when the RFID reader accesses a predefined model during its inventory scanning process. The present invention also provides necessary information to the logistics system regarding need to take action on a certain device(s), such as to remove an item from inventory due to a date stamp. For example, should the reader scan a particular meter model with a manufacture date that the server 212 of FIG. 2 determines is related to an obsolete version of software, the server would notify the operator to “pull” the unit from inventory and submit it for a software update.

The present invention might also be used to identify or search for a specific item in a group of items, where each item is marked with an RFID tag. For example, file folders or other such items, located in a file or storage room, could be each marked with an RFID tag. If a specific file folder needed to be located, a reader could be used to interrogate the tags in the file room. Multiple responses to then interrogation signal would be received by the reader, including the unique identifiers. If the file folder of interest is in the room, its unique identifier should be received and identified. To gather further information from the tag of interest, all tags or all other tags would be disabled and the tag associated with the file of interest activated or an enabling signal transmitted. The return of response information could then be used to obtain further information related to the file of interest.

The present invention could also be used to locate and identify equipment, such as for example, postage meters. A specific meter could be located and compared against stored location information to determine if the meter is being used in the proper location. Or, after locating the meter, the tag could be interrogated to determine update or version information, as well as be updated upon installation of new hardware or software.

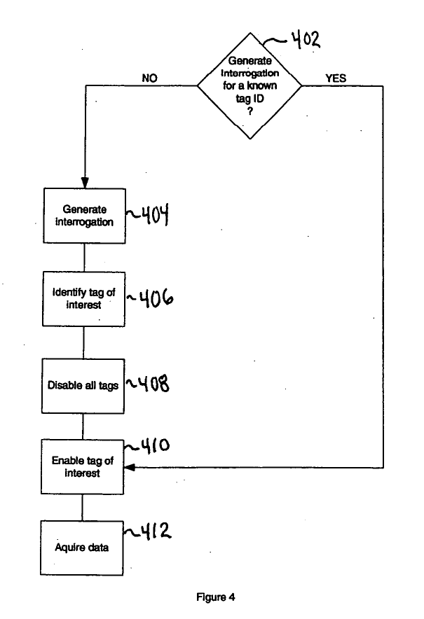

Referring to FIG. 4, in one embodiment, the reader 202 of FIG. 2 determines 402 whether to generate an interrogation for a known tag ID or a general interrogation. If not for a known tag ID, the reader 202 of FIG. 2 generates 404 an interrogation command or signal. The tag of interest is then identified 406. All of the tags are then disabled 408 via a disable command transmitted by the reader 202. The selected or identified tag is then enabled 410 or turned on and the data from the tag is acquired 412. The process of turning tags on and off continues. In another embodiment, all of the tag ID's in the area are acquired. The tags are then disabled and each one enabled one-at-a-time based on the identified tag ID's.

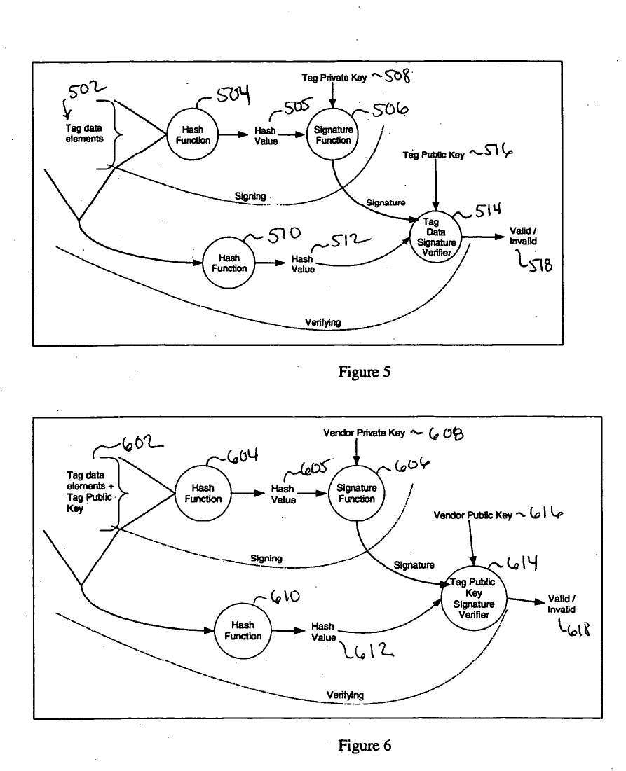

FIG. 5 illustrates one embodiment of a validation process for data signatures of RFID tags. The tag data elements 502 are applied to a hash function 504 to result in a hash value 505. The hash value 505 and the tag private key 508 are combined to produce the signature function 506. During verification, the hash value 512, produced from the hash function 510 as applied to the tag data elements 502, is inputted to the tag data signature verifier 514, together with the signature and the tag public key 516. The result 518 determines the validity or invalidity of the tag data elements 502 after transmission.

FIG. 6 illustrates the validation of the key used by the signature function 606. The tag data elements and the tag public key 602 are hashed via a hash function 604 to produce a hash valve 605. The hash value 605 and vendor private key 608 are used to produce the signature function 606. The vendor public key 616 is used together with the signature function key 606 and hash value in the tag public key signature verifier to determine if the tag data elements are signed by the proper authority and are determined to be valid or invalid 518.

The present invention can utilize radio frequency identification to provide RFID tags in metering products that identify the state of the product as related to such parameters as model, date of manufacture, expiration date, customer, etc. A tag of interest is identified based on information previously stored or obtained. A command to turn off all tags is transmitted to the group of tags. Based on the information corresponding to the tag of interest, such as its ID, a command is issued to selectively enable that tag. The data from that tag is then acquired. Each tag is then selectively enabled to acquire the tag's data.

The present invention generally allows the identification and isolation of one RFID tag response from another where multiple RFID tags are in the same proximity. In order to isolate one tag from another, the identifier associated with a tag of interest is obtained. Generally, this can be the result of an initial interrogation signal transmitted by the reader. Then all other tags can be disabled and the information associated with the tag of interest can be retrieved or updated without interference from any other tag signals.

It should be understood that the foregoing description is only illustrative of the invention. Various alternatives and modifications can be devised by those skilled in the art without departing from the invention. Accordingly, the present invention is intended to embrace all such alternatives, modifications and variances that fall within the scope of the appended claims.

1. A method of selectively identifying at least one RFID tag from another RFID during interrogation of a plurality of RFID tags comprising:
transmitting an interrogation signal to one or more RFID tags in a plurality of RFID tags;
identifying a tag of interest by a unique identifier associated with the tag of interest;
turn off all tags being interrogated;
turn on the tag of interest by the unique identifier; and
acquire data associated with the tag of interest after interrogating the tag.

2. The method of claim 1 wherein the step of turning off all tags being interrogated further comprises turning off all tags except the tag of interest.

3. The method of claim 1 further comprising authenticating a signal received from the tag using public key technology.

4. The method of claim 1 further comprising selectively isolating a subset of tags in the plurality of tags by enabling or disabling tags based on identifier information received related to the subset of tags.

5. The method of claim 4 further comprising interrogating the enabled subset of tags, identifying a tag of interest in the enabled subset of tags and disabling all other tags in order to retrieve data from the tag of interest.

6. The method of claim 1 further comprising authenticating and verifying the unique identifier using public key cryptography and digital signing techniques.

7. The method of claim 1 further comprising validating a digital signature associated with the acquired data in order to verify a validity and origin of the acquired data.

8. A method of selectively interrogating an RFID tag in a plurality of RFID tags comprising:
detecting more than one tag response to an RFID tag interrogation signal;
transmitting a signal to terminate all unwanted RFID tag responses;
transmitting another signal to enable at least one RFID tag of interest; and
interrogating the at least one RFID tag of interest.

9. The method of claim 8 wherein the step of terminating unwanted RFID tag responses comprises disabling all RFID tags from responding to an interrogation signal.

10. The method of claim 8 wherein the step of terminating unwanted RFID tag responses comprises disabling all RFID tags from responding except for an RFID tag of interest.

11. The method of claim 8 further comprising:
reading data from the tag;
interpreting the data; and
uploading new data to the tag.

12. The method of claim 8 further comprising:
retrieving data from the tag of interest;
enabling the disabled RFID tags;
identifying another tag of interest;
disabling all other unwanted tags; and
interrogating the another identified tag of interest.
